(19) United States
(12) Patent Application Publication
(10) Pub. No.: US 2022/0252972 A1
(43) Pub. Date: Aug. 11, 2022

(54) MASK BLANK, PHASE SHIFT MASK AND METHOD FOR PRODUCING SEMICONDUCTOR DEVICE

(71) Applicant: HOYA CORPORATION, Tokyo (JP)

(72) Inventors: Hitoshi MAEDA, Tokyo (JP); Osamu NOZAWA, Tokyo (JP)

(73) Assignee: HOYA CORPORATION, Tokyo (JP)

(21) Appl. No.: 17/628,655

(22) PCT Filed: Aug. 26, 2020
(86) PCT No.: PCT/JP2020/032144

§ 371 Date: Jan. 20, 2022

(30) Foreign Application Priority Data
Sep. 5, 2019 (JP) 2019-161896

(51) Int. Cl. G03F 1/32; H01L 21/027

(52) U.S. Cl. CPC G03F 1/32; H01L 21/0274

(57) ABSTRACT

Provided is a mask blank that can manufacture a phase shift mask.

Provided is a mask blank having a phase shift film on a transparent substrate, the phase shift film contains hafnium, silicon, and oxygen, a ratio of a hafnium content to a total content of hafnium and silicon in the phase shift film by atom % is 0.4 or more, a refractive index n of the phase shift film to a wavelength of an exposure light of an Arf excimer laser is 2.5 or more, and an extinction coefficient k of the phase shift film to a wavelength of the exposure light is 0.30 or less.

### CROSS-REFERENCE TO RELATED APPLICATIONS

This application is the National Stage of International Application No. PCT/JP2020/032144, filed Aug. 26, 2020, which claims priority to Japanese Patent Application No. 2019-161896, filed Sep. 5, 2019, and the contents of which is incorporated by reference.

### TECHNICAL FIELD

This disclosure relates to a mask blank for a phase shift mask, a phase shift mask, and a method of manufacturing a semiconductor device.

### BACKGROUND ART

In a manufacturing process of a semiconductor device, a fine pattern is formed using a photolithography method. A number of transfer masks are usually used to form the fine pattern. In order to miniaturize a pattern of a semiconductor device, in addition to miniaturization of a mask pattern formed in a transfer mask, it is necessary to shorten a wavelength of an exposure light source used in photolithography. In recent years, application of an ArF excimer laser (wavelength 193 nm) is increasing as an exposure light source in the manufacture of semiconductor devices.

A type of a transfer mask is a half tone phase shift mask. As a mask blank for a half tone phase shift mask, a mask blank having a structure where a phase shift film formed of a material containing silicon and nitrogen, a light shielding film formed of a material containing a chromium-based material, and an etching mask film (hard mask film) formed of an inorganic material are stacked on a transparent substrate has been known. In the case of manufacturing a half tone phase shift mask using this mask blank, initially, an etching mask film is patterned through dry etching by fluorine-based gas with a resist pattern formed in a surface of the mask blank as a mask, subsequently a light shielding film is patterned through dry etching by mixed gas of chlorine and oxygen with an etching mask film as a mask, and further, the phase shift film is patterned through dry etching by fluorine-based gas with a pattern of the light shielding film as a mask.

For example, Patent Document 1 proposes a half tone phase shift mask having a phase shift film formed of a high-nitrided SiN-based material having a nitrogen content of 50% or more, and having a function to transmit an ArF excimer laser exposure light at a transmittance of 10% or more, and a function to generate a phase difference of 150 degrees or more and 200 degrees or less.

### PRIOR ART PUBLICATIONS

### Patent Documents

### [Patent Document b 1]

Japanese Patent Application Publication 2018-91889

### SUMMARY OF THE DISCLOSURE

### Problems to be Solved by the Disclosure

In recent years, with miniaturization and complexity of patterns, there has been a demand for a phase shift film having a higher transmittance to an ArF excimer laser exposure light in order to enable pattern transfer with a higher resolution. Phase shift effect can be enhanced by enhancing the transmittance to an exposure light. Therefore, an exposure margin can be secured when a phase shift mask having the phase shift film is set on an exposure apparatus and then an object to be transferred (resist film on a semiconductor substrate, etc.) is exposure-transferred. To enhance the transmittance to an exposure light, it is effective to include oxygen in a phase shift film. However, including oxygen in a phase shift film causes a decrease in a refractive index of the phase shift film, also causing a decrease in a phase difference to be obtained. In order to compensate for the decreased phase difference and to secure a desired phase difference, it is necessary to increase a film thickness of a phase shift film. However, increasing a film thickness of a phase shift film causes a decrease in an optical performance, causing a problem of decrease in a CD in-plane uniformity of a transfer image when an object to be transferred is exposure-transferred.

This disclosure was made to solve the conventional problem, and an aspect is to provide a mask blank that can manufacture a phase shift mask that can enhance phase shift effect to an ArF excimer laser exposure light, that can secure an exposure margin, and having a good optical performance; and another aspect is to provide a phase shift mask that can enhance phase shift effect to an ArF excimer laser exposure light, that can secure an exposure margin, and having a good optical performance. This disclosure provides a method of manufacturing a semiconductor device using such a phase shift mask.

### Means for Solving the Problem

As means for solving the above problem, this disclosure includes the following configurations.

### (Configuration 1)

A mask blank including a phase shift film on a transparent substrate,

in which the phase shift film contains hafnium, silicon, and oxygen,

in which a ratio of a hafnium content to a total content of hafnium and silicon in the phase shift film by atom % is 0.4 or more,

in which a refractive index n of the phase shift film to a wavelength of an exposure light of an Arf excimer laser is 2.5 or more, and

in which an extinction coefficient k of the phase shift film to a wavelength of the exposure light is 0.30 or less.

### (Configuration 2)

The mask blank according to Configuration 1, in which a refractive index n of the phase shift film to a wavelength of the exposure light is 2.9 or less.

### (Configuration 3)

The mask blank according to Configuration 1 or 2, in which an extinction coefficient k of the phase shift film to a wavelength of the exposure light is 0.05 or more.

### (Configuration 4)

The mask blank according to any of Configurations 1 to 3, in which the phase shift film has an oxygen content of 60 atom % or more.

### (Configuration 5)

The mask blank according to any of Configurations 1 to 4, in which the phase shift film has a film thickness of 65 nm or less.

### (Configuration 6)

The mask blank according to any of Configurations 1 to 5, in which the phase shift film contains hafnium, silicon, and oxygen at a total content of 90 atom % or more.

### (Configuration 7)

The mask blank according to any of Configurations 1 to 6, in which the phase shift film has a function to transmit the exposure light at a transmittance of 20% or more, and a function to generate a phase difference of 150 degrees or more and 210 degrees or less between the exposure light transmitted through the phase shift film and the exposure light transmitted through the air for a same distance as a thickness of the phase shift film.

### (Configuration 8)

The mask blank according to any of Configurations 1 to 7 including a light shielding film on the phase shift film.

### (Configuration 9)

A phase shift mask including a phase shift film having a transfer pattern on a transparent substrate,

in which the phase shift film contains hafnium, silicon, and oxygen,

in which a ratio of a hafnium content to a total content of hafnium and silicon in the phase shift film by atom % is 0.4 or more,

in which a refractive index n of the phase shift film to a wavelength of an exposure light of an Arf excimer laser is 2.5 or more, and

in which an extinction coefficient k of the phase shift film to a wavelength of the exposure light is 0.30 or less.

### (Configuration 10)

The phase shift mask according to Configuration 9, in which a refractive index n of the phase shift film to a wavelength of the exposure light is 2.9 or less.

### (Configuration 11)

The phase shift mask according to Configuration 9 or 10, in which an extinction coefficient k of the phase shift film to a wavelength of the exposure light is 0.05 or more.

### (Configuration 12)

The phase shift mask according to any of Configurations 9 to 11, in which the phase shift film has an oxygen content of 60 atom % or more.

### (Configuration 13)

The phase shift mask according to any of Configurations 9 to 12, in which the phase shift film has a film thickness of 65 nm or less.

### (Configuration 14)

The phase shift mask according to any of Configurations 9 to 13, in which the phase shift film contains hafnium, silicon, and oxygen at a total content of 90 atom % or more.

### (Configuration 15)

The phase shift mask according to any of Configurations 9 to 14, in which the phase shift film has a function to transmit the exposure light at a transmittance of 20% or more, and a function to generate a phase difference of 150 degrees or more and 210 degrees or less between the exposure light transmitted through the phase shift film and the exposure light transmitted through the air for a same distance as a thickness of the phase shift film.

### (Configuration 16)

The phase shift mask according to any of Configurations 9 to 15 including a light shielding film having a pattern including a light shielding band on the phase shift film.

### (Configuration 17)

A method of manufacturing a semiconductor device including the step of transferring a transfer pattern to a resist film on a semiconductor substrate by exposure using the phase shift mask according to Configuration 16.

### Effect of the Disclosure

The mask blank of this disclosure having the above configuration includes a phase shift film on a transparent substrate, featured in that the phase shift film contains hafnium, silicon, and oxygen, a ratio of a hafnium content to a total content of hafnium and silicon in the phase shift film by atom % being 0.4 or more, a refractive index n of the phase shift film to a wavelength of an exposure light of an Arf excimer laser being 2.5 or more, and an extinction coefficient k of the phase shift film to a wavelength of the exposure light being 0.10 or more and 0.30 or less. Therefore, a phase shift mask can be manufactured that can enhance phase shift effect to an exposure light of an ArF excimer laser, that can secure an exposure margin, and having a good optical performance. Moreover, in manufacturing a semiconductor device using the phase shift mask, a pattern can be transferred to a resist film, etc. on the semiconductor device with excellent precision.

### BRIEF DESCRIPTION OF THE DRAWINGS

FIG. 1 is a schematic cross-sectional view of an embodiment of the mask blank.

FIGS. 2A-2G are schematic cross-sectional views showing a manufacturing step of the phase shift mask.

### EMBODIMENTS FOR CARRYING OUT THE DISCLOSURE

The embodiments of this disclosure are explained below. First, the proceeding that has resulted in this disclosure is described. As mentioned above, conventional phase shift films are formed of a material containing silicon and nitrogen, and main components were silicon and nitrogen. While there existed a phase shift film containing a metal such as molybdenum, those containing silicon and nitrogen as main components were the majority. In contrast thereto, the inventors first included hafnium, silicon, and oxygen in the material forming the phase shift film. The inventors focused on a ratio of a hafnium content [atom %] to a total content of hafnium and silicon [atom %] (hereafter Hf/[Hf+Si] ratio) in a phase shift film, a refractive index n and an extinction coefficient k in a wavelength of an ArF excimer laser exposure light (hereafter may be simply referred to as refractive index n and extinction coefficient k). The inventors found that there is a correlation between the Hf/[Hf+Si] ratio and a refractive index n and an extinction coefficient k. A refractive index n and an extinction coefficient k of a phase shift film significantly relate to determination of a phase difference, transmittance, and film thickness of a phase shift film. The inventors further studied and found that, in a phase shift film containing hafnium, silicon, and oxygen, by applying Hf/[Hf+Si] ratio of 0.4 or more, a refractive index n of 2.5 or more, and an extinction coefficient k of 0.30 or less, a phase shift mask can be manufactured that can enhance phase shift effect to an ArF excimer laser exposure light, that can secure an exposure margin, and having a good optical performance.

Detailed configurations of this disclosure described above are explained below based on the drawings. In the drawings, identical reference numerals are applied to similar components.

### (Mask Blank)

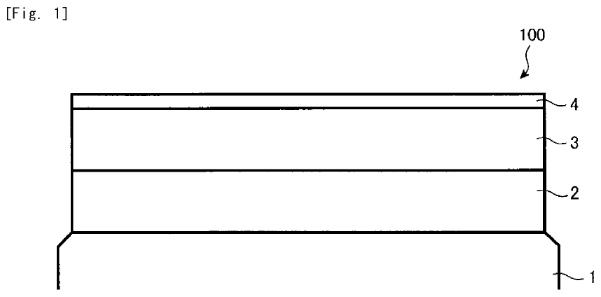

FIG. 1 shows a schematic configuration of an embodiment of a mask blank. A mask blank 100 shown in FIG. 1 has a configuration where a phase shift film 2, a light shielding film 3, and a hard mask film 4 are stacked in this order on one main surface of a transparent substrate 1. The mask blank 100 can have a configuration without the hard mask film 4 as desired. Further, the mask blank 100 can have a configuration where the hard mask film 4 has a resist film stacked thereon as desired. The detail of major elements of the mask blank 100 is explained below.

### [Transparent Substrate]

The transparent substrate 1 is formed of materials having a good transmittance to an exposure light used in an exposure step in lithography. As such materials, synthetic quartz glass, aluminosilicate glass, soda-lime glass, low thermal expansion glass (SiO₂—TiO₂ glass, etc.), and various other glass substrates can be used. Particularly, a substrate using synthetic quartz glass has high transmittance to an ArF excimer laser light (wavelength: about 193 nm), which can be used preferably as the transparent substrate 1 of the mask blank 100.

The exposure step in lithography as used herein refers to an exposure step of lithography using a phase shift mask produced by using the mask blank 100, and the exposure light refers to an ArF excimer laser light (wavelength: 193 nm), unless otherwise specified.

A refractive index of the material forming the transparent substrate 1 to an exposure light is preferably 1.5 or more and 1.6 or less, more preferably 1.52 or more and 1.59 or less, and even more preferably 1.54 or more and 1.58 or less.

### [Phase Shift Film]

The phase shift film 2 preferably has a function to transmit an exposure light at a transmission of 20% or more. This is to generate a sufficient phase shift effect between the exposure light transmitted through the interior of the phase shift film 2 and the exposure light transmitted through the air. Further, a transmittance of the phase shift film 2 to an exposure light is preferably 75% or less, and more preferably 70% or less. This is to retain a film thickness of the phase shift film 2 within a proper range to secure an optical performance.

To obtain a proper phase shift effect, the phase shift film 2 is preferably adjusted to have a function to generate a phase difference of 150 degrees or more and 210 degrees or less between an exposure light transmitted through the phase shift film 2 and an exposure light that transmitted through the air for the same distance as a thickness of the phase shift film 2. A phase difference in the phase shift film 2 is preferably 155 degrees or more, and more preferably 160 degrees or more. On the other hand, a phase difference of the phase shift film 2 is preferably 195 degrees or less, and more preferably 190 degrees or less.

To at least satisfy each aforementioned condition of a transmittance and a phase difference in the entire phase shift film 2, a refractive index n to a wavelength of an exposure light (hereafter simply referred to as refractive index n) is preferably 2.5 or more, more preferably 2.6 or more, and further preferably 2.62 or more. Further, a refractive index n of the phase shift film 2 is preferably 2.9 or less, and more preferably 2.88 or less. An extinction coefficient k of the phase shift film 2 is preferably 0.05 or more, more preferably more than 0.1, and even more preferably 0.12 or more. Further, an extinction coefficient k of the phase shift film 2 to a wavelength of an exposure light (hereafter simply referred to as extinction coefficient k) is preferably 0.30 or less, and more preferably 0.28 or less. A refractive index n and an extinction coefficient k of the phase shift film 2 are values derived by regarding the entire phase shift film 2 as a single, optically uniform layer.

A refractive index n and an extinction coefficient k of a thin film including the phase shift film 2 are not determined only by the composition of the thin film. Film density and crystal state of the thin film etc. are also the factors that affect a refractive index n and an extinction coefficient k. Therefore, the conditions in forming a thin film by reactive sputtering are adjusted so that the thin film has desired refractive index n and extinction coefficient k. For allowing the phase shift film 2 to have a refractive index n and an extinction coefficient k within the above range, not only a ratio of mixed gas of noble gas and reactive gas (oxygen gas, nitrogen gas, etc.) is adjusted in forming the film by reactive sputtering, but various other adjustments are made upon forming the film by reactive sputtering, such as pressure in a film forming chamber, power applied to the sputtering target, and positional relationship such as distance between the target and the transparent substrate 1. These film forming conditions are unique to film forming apparatuses, and are adjusted properly so that a thin film to be formed has desired refractive index n and extinction coefficient k.

For securing an optical performance, a film thickness of the phase shift film 2 is preferably 65 nm or less, and more preferably 62 nm or less. Further, a film thickness of the phase shift film 2 is preferably 50 nm or more, and more preferably 52 nm or more to secure a function to generate a desired phase difference.

The phase shift film 2 is preferably formed of a material containing hafnium, silicon, and oxygen. A total content of hafnium, silicon, and oxygen of the phase shift film 2 is preferably 90 atom % or more, more preferably 95 atom % or more, and even more preferably 97 atom % or more. This enhances a transmittance as well as restrains increase of a film thickness caused by including oxygen. Further, the phase shift film 2 particularly preferably consists only of hafnium, silicon, and oxygen, excluding noble gas and impurities that are incorporated upon film formation. The phase shift film 2 can be patterned through dry etching using chlorine-based gas containing boron, preferably mixed gas of BCl₃ gas and Cl₂ gas, and has sufficient etching selectivity to the light shielding film 3 that is mentioned below.

An oxygen content of the phase shift film 2 is preferably 60 atom % or more, and more preferably 62 atom % or more in view of enhancing a transmittance. An oxygen content of the phase shift film 2 is preferably 67 atom % or less, and more preferably 66 atom % or less in view of reducing surface roughness of the film. As long as the above optical characteristics are satisfied, the phase shift film 2 can further contain one or more elements selected from a metalloid element, a non-metallic element, and a metal element respectively within the range of 3 atom % or less. Particularly, non-heavy elements such as nitrogen, carbon, and hydrogen are inevitably permitted respectively within the range of 5 atom % or less.

Further, a ratio of a hafnium content to a total content of hafnium and silicon in the phase shift film 2 by atom % (Hf/[Hf+Si] ratio) is preferably 0.4 or more, and more preferably 0.5 or more. This is for allowing a film thickness of the phase shift film 2 within a proper range. Further, this Hf/[Hf+Si] ratio is preferably 0.9 or less, and more preferably 0.8 or less. This is for enhancing a transmittance of the phase shift film 2.

While the phase shift film 2 is preferably a single layer film with a uniform composition, it is not necessarily limited thereto, and can be formed of multiple layers, and can have a configuration with a composition gradient in a thickness direction.

The phase shift film 2 does not have to satisfy the range of Hf/[Hf+Si] ratio, a refractive index n, and an extinction coefficient k given above in all regions in the film. It is sufficient for the phase shift film 2 to satisfy the range of Hf/[Hf+Si] ratio, a refractive index n, and an extinction coefficient k given above when the entire phase shift film 2 is regarded as a single, uniform film. When the phase shift film 2 has a multilayer structure, it is not necessary for all the layers forming the phase shift film 2 to satisfy Hf/[Hf+Si] ratio, a refractive index n, and an extinction coefficient k given above. It is sufficient for the phase shift film 2 to satisfy the range of Hf/[Hf+Si] ratio, a refractive index n, and an extinction coefficient k when the entire phase shift film 2 is regarded as a single film. For example, the phase shift film 2 may be formed of a plurality of layers, and the uppermost layer (layer forming the surface of the phase shift film 2 and being opposite to the transparent substrate 1) may be formed of a material containing silicon and oxygen as main components (total content of silicon and oxygen is 80 atom % or more).

### [Light Shielding Film]

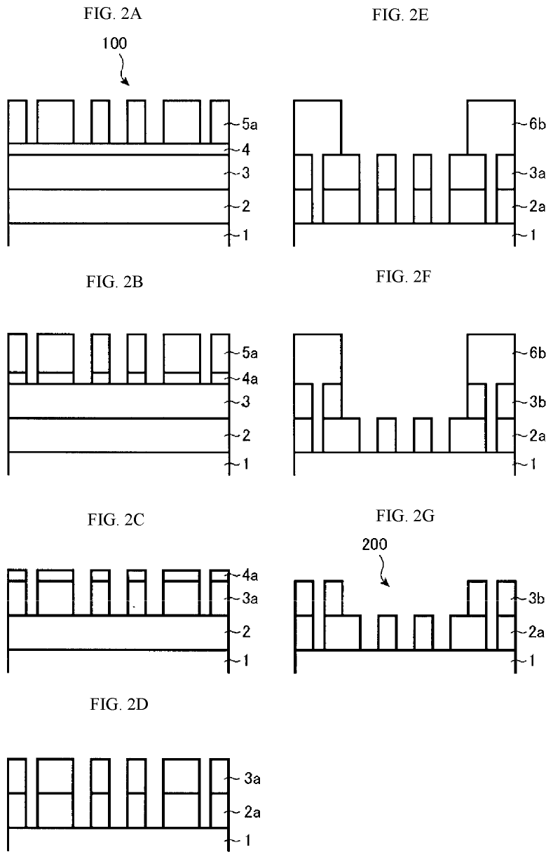

The mask blank 100 has a light shielding film 3 on the phase shift film 2. Generally, in a phase shift mask, an outer peripheral region of a region to which a transfer pattern is formed (transfer pattern forming region) is desired to secure optical density (OD) with a predetermined value or more so that the resist film is not affected by an exposure light that transmitted through the outer peripheral region when a resist film on a semiconductor wafer is exposure-transferred using an exposure apparatus. The outer peripheral region of a phase shift mask preferably has an OD of 2.8 or more, and more preferably 3.0 or more. As mentioned above, the phase shift film 2 has a function to transmit an exposure light at a predetermined transmittance, and it is difficult to secure an optical density of a predetermined value with the phase shift film 2 alone. Therefore, at the stage of manufacturing the mask blank 100, it is necessary to stack the light shielding film 3 on the phase shift film 2 to secure optical density that would otherwise be insufficient. With such a configuration of the mask blank 100, the phase shift mask 200 securing a predetermined value of optical density on the outer peripheral region can be manufactured by removing the light shielding film 3 of the region which uses the phase shift effect (basically transfer pattern forming region) during manufacture of the phase shift mask 200 (see FIGS. 2A-2G).

A single layer structure and a stacked structure of two or more layers are applicable to the light shielding film 3. Further, each layer in the light shielding film 3 of a single layer structure and the light shielding film 3 with a stacked structure of two or more layers may be configured by approximately the same composition in the thickness direction of the layer or the film, or with a composition gradient in the thickness direction of the layer.

The mask blank 100 of the embodiment shown in FIG. 1 is configured by stacking the light shielding film 3 on the phase shift film 2 without an intervening film. For the light shielding film 3 of this configuration, it is necessary to apply a material having a sufficient etching selectivity to etching gas used in forming a pattern in the phase shift film 2. The light shielding film 3 in this case is preferably formed of a material containing chromium. Materials containing chromium for forming the light shielding film 3 can include, in addition to chromium metal, a material containing chromium and one or more elements selected from oxygen, nitrogen, carbon, boron, and fluorine.

While a chromium-based material is generally etched by mixed gas of chlorine-based gas and oxygen gas, an etching rate of the chromium metal with respect to the etching gas is not greatly high. Considering enhancing an etching rate of the etching gas formed with mixed gas of chlorine-based gas and oxygen gas, the material forming the light shielding film 3 preferably contains chromium and one or more elements selected from oxygen, nitrogen, carbon, boron, and fluorine. Further, one or more elements among molybdenum, indium, and tin can be included in the material containing chromium for forming the light shielding film 3. Including one or more elements among molybdenum, indium, and tin can increase an etching rate to mixed gas of chlorine-based gas and oxygen gas.

The light shielding film 3 can be formed of a material containing silicon as long as an etching selectivity to the material forming the phase shift film 2 can be obtained for dry etching. Particularly, a material containing a transition metal and silicon has high light shielding performance, which enables reduction of a thickness of the light shielding film 3. The transition metal to be included in the light shielding film 3 includes one metal among molybdenum (Mo), tantalum (Ta), tungsten (W), titanium (Ti), chromium (Cr), hafnium (Hf), nickel (Ni), vanadium (V), zirconium (Zr), ruthenium (Ru), rhodium (Rh), zinc (Zn), niobium (Nb), palladium (Pd), etc., or an alloy of these metals. Metal elements other than the transition metal elements to be included in the light shielding film 3 include aluminum (Al), indium (In), tin (Sn), gallium (Ga), etc.

On the other hand, the light shielding film 3 can have a structure where a layer containing chromium and a layer containing a transition metal and silicon are stacked, in this order, from the phase shift film 2 side. Concrete matters on the materials of the layer containing chromium and the layer containing a transition metal and silicon in this case are similar to the case of the light shielding film 3 described above.

### [Hard Mask Film]

The hard mask film 4 is provided in contact with a surface of the light shielding film 3. The hard mask film 4 is a film formed of a material having etching durability to etching gas used in etching of the light shielding film 3. It is sufficient for the hard mask film 4 to have a film thickness that can function as an etching mask until dry etching for forming a pattern in the light shielding film 3 is completed, and basically the hard mask film 4 is not subjected to limitation of optical characteristics. Therefore, a thickness of the hard mask film 4 can be reduced significantly compared to a thickness of the light shielding film 3.

In the case where the light shielding film 3 is formed of a material containing chromium, the hard mask film 4 is preferably formed of a material containing silicon. Since the hard mask film 4 in this case tends to have low adhesiveness with a resist film of an organic material, it is preferable to treat the surface of the hard mask film 4 with HMDS (Hexamethyldisilazane) to enhance surface adhesiveness. The hard mask film 4 in this case is more preferably formed of SiO₂, SiN, SiON or the like.

Further, in the case where the light shielding film 3 is formed of a material containing chromium, materials containing tantalum are also applicable as the materials of the hard mask film 4, in addition to the materials given above. The material containing tantalum in this case includes, in addition to tantalum metal, a material containing tantalum and one or more elements selected from nitrogen, oxygen, boron, and carbon, for example, Ta, TaN, TaO, TaON, TaBN, TaBO, TaBON, TaCN, TaCO, TaCON, TaBCN, TaBOCN, etc. Further, in the case where the light shielding film 3 is formed of a material containing silicon, the hard mask film 4 is preferably formed of the material containing chromium given above.

In the mask blank 100, a resist film of an organic material is preferably formed with a film thickness of 100 nm or less in contact with a surface of the hard mask film 4. In the case of a fine pattern to meet DRAM hp32nm generation, a SRAF (Sub-Resolution Assist Feature) with 40 nm line width may be provided on a transfer pattern (phase shift pattern) to be formed in the hard mask film 4. However, even in this case, the cross-sectional aspect ratio of the resist pattern can be reduced to 1:2.5 so that collapse and peeling of the resist pattern can be restrained in rinsing and developing, etc. of the resist film. Incidentally, the resist film preferably has a film thickness of 80 nm or less.

### [Resist Film]

In the mask blank 100, a resist film of an organic material is preferably formed with a film thickness of 100 nm or less in contact with a surface of the hard mask film 4. In the case of a fine pattern compatible with the DRAM hp32nm generation, SRAF (Sub-Resolution Assist Feature) having a line width of 40 nm may be provided in a light shielding pattern that is to be formed in the light shielding film 3. However, also in this case, as described above, a film thickness of the resist film can be controlled to be small as a result of providing the hard mask film 4, and as a consequence, a cross-sectional aspect ratio of the resist pattern formed of the resist film can be set as low as 1:2.5. Therefore, collapse or peeling of the resist pattern during the development, rinsing, etc. of the resist film can be restrained. Incidentally, the resist film preferably has a film thickness of 80 nm or less. The resist film is preferably a resist for electron beam writing exposure, and it is more preferable that the resist is a chemically amplified resist.

### [Manufacturing Procedure of Mask Blank]

The mask blank 100 of the above configuration is manufactured through the following procedure. First, a transparent substrate 1 is prepared. This transparent substrate 1 includes an end surface and main surfaces polished into a predetermined surface roughness (e.g., root mean square roughness Rq of 0.2 nm or less in an inner region of a square of 1 μm side), and thereafter subjected to predetermined cleaning treatment and drying treatment.

Next, a phase shift film 2 is formed on the transparent substrate 1 by sputtering method. After the phase shift film 2 is formed, annealing is properly carried out at a predetermined heating temperature. Next, the light shielding film 3 is formed on the phase shift film 2 by sputtering method. Subsequently, the hard mask film 4 is formed on the light shielding film 3 by sputtering method. In film formation by sputtering method, a sputtering target and sputtering gas containing materials forming each film at a predetermined composition ratio are used, and moreover, mixed gas of noble gas and reactive gas mentioned above is used as sputtering gas as necessary. Thereafter, in the case where the mask blank 100 includes a resist film, the surface of the hard mask film 4 is subjected to HMDS (Hexamethyldisilazane) treatment as necessary. Next, a resist film is formed by coating methods such as spin coating on the surface of the hard mask film 4 after HMDS treatment to complete the mask blank 100.

### <Manufacturing Method of Phase Shift Mask>

FIGS. 2A-2G show a phase shift mask 200 according to an embodiment of this disclosure manufactured from the mask blank 100 of the above embodiment, and its manufacturing process. As shown in FIG. 2G, the phase shift mask 200 is featured in that a phase shift pattern 2a as a transfer pattern is formed in a phase shift film 2 of the mask blank 100, and that a light shielding pattern 3b having a pattern including a light shielding band is formed in a light shielding film 3. In the case of a configuration where a hard mask film 4 is provided on the mask blank 100, the hard mask film 4 is removed during manufacture of the phase shift mask 200.

The method of manufacturing the phase shift mask 200 of the embodiment of this disclosure uses the mask blank 100 mentioned above, the method featured in including the steps of forming a transfer pattern in the light shielding film 3 by dry etching; forming a transfer pattern in the phase shift film 2 by dry etching with the light shielding film 3 having the transfer pattern as a mask; and forming a light shielding pattern 3b in the light shielding film 3 by dry etching with a resist film (resist pattern 6b) having a light shielding pattern as a mask. The method of manufacturing the phase shift mask 200 of this disclosure is explained below according to the manufacturing steps shown in FIGS. 2A-2G. Explained herein is the method of manufacturing the phase shift mask 200 using the mask blank 100 having the hard mask film 4 stacked on the light shielding film 3. Further, explained herein is the case where a material containing chromium is applied to the light shielding film 3, and a material containing silicon is applied to the hard mask film 4.

First, a resist film is formed in contact with the hard mask film 4 of the mask blank 100 by spin coating. Next, a first pattern, which is a transfer pattern (phase shift pattern) to be formed in the phase shift film 2, was written by exposure with an electron beam on the resist film, and a predetermined treatment such as developing was conducted, to thereby form a first resist pattern 5a having a phase shift pattern (see FIG. 2A). Subsequently, dry etching was conducted using fluorine-based gas with the first resist pattern 5a as a mask, and a first pattern (hard mask pattern 4a) was formed in the hard mask film 4 (see FIG. 2B).

Next, after removing the resist pattern 5a, dry etching was conducted using mixed gas of chlorine-based gas and oxygen gas with the hard mask pattern 4a as a mask, and a first pattern (light shielding pattern 3a) was formed in the light shielding film 3 (see FIG. 2C). Subsequently, dry etching was conducted using chlorine-based gas containing boron with the light shielding pattern 3a as a mask, and a first pattern (phase shift pattern 2a) was formed in the phase shift film 2, and also the hard mask pattern 4a was removed (see FIG. 2D).

Next, a resist film was formed on the mask blank 100 by spin coating. Next, a second pattern, which is a pattern (light shielding pattern) to be formed in the light shielding film 3, was written by exposure with an electron beam on the resist film, and a predetermined treatment such as developing was conducted, to thereby form a second resist pattern 6b having a light shielding pattern (see FIG. 2E). Subsequently, dry etching was conducted using mixed gas of chlorine-based gas and oxygen gas with the second resist pattern 6b as a mask, and a second pattern (light shielding pattern 3b) was formed in the light shielding film 3 (see FIG. 2F). Further, the second resist pattern 6b was removed, predetermined treatments such as cleaning were carried out, and the phase shift mask 200 was obtained (see FIG. 2G).

There is no particular limitation on chlorine-based gas to be used for the dry etching described above, as long as Cl is included. Examples of the chlorine-based gas include Cl₂, SiCl₂, CHCl₃, CH₂Cl₂, CCl₄, and BCl₃. Further, there is no particular limitation on chlorine-based gas containing boron to be used for the dry etching described above, as long as B and Cl are included, for example, BCl₃. Particularly, mixed gas of BCl₃ gas and Cl₂ gas is preferable for having relatively high etching rate to hafnium.

The phase shift mask 200 manufactured by the manufacturing method shown in FIGS. 2A-2G is a phase shift mask having a phase shift film 2 (phase shift pattern 2a) having a transfer pattern on the transparent substrate 1.

By manufacturing the phase shift mask 200 as mentioned above, a phase shift mask 200 can be obtained that can enhance phase shift effect to an exposure light of an ArF excimer laser, that can secure an exposure margin, and having a good optical performance.

Further, the method of manufacturing the semiconductor device of this disclosure is featured in including the step of transferring a transfer pattern to a resist film on a semiconductor substrate by exposure using the phase shift mask 200 given above.

Since the phase shift mask 200 and the mask blank 100 of this disclosure have the effects as described above, when the phase shift mask 200 is set on a mask stage of an exposure apparatus using ArF excimer laser as an exposure light to transfer a transfer pattern to a resist film on a semiconductor device by exposure, the transfer pattern can be transferred in the resist film on the semiconductor device at a high CD in-plane uniformity. Therefore, in the case where a pattern of this resist film is used as a mask and a lower layer film therebelow was dry etched to form a circuit pattern, a highly precise circuit pattern without short-circuit of wiring and disconnection caused by reduction of CD in-plane uniformity can be formed.

### EXAMPLES

Examples 1 to 4 and Comparative Examples 1 to 4 are given below to further concretely describe the embodiments of this disclosure.

### Example 1

### [Manufacture of Mask Blank]

In view of FIG. 1, a transparent substrate 1 formed of a synthetic quartz glass with a size of a main surface of about 152 mm×about 152 mm and a thickness of about 6.35 mm was prepared. End surfaces and main surfaces of the transparent substrate 1 were polished to a predetermined surface roughness (0.2 nm or less Rq), and thereafter subjected to predetermined cleaning treatment and drying treatment. Each optical characteristic of the transparent substrate 1 was measured using a spectroscopic ellipsometer (M-2000D manufactured by J. A. Woollam), and a refractive index was 1.556 and an extinction coefficient was 0.000 to a light of 193 nm wavelength.

Next, the transparent substrate 1 was placed in a single-wafer RF sputtering apparatus, and by reactive sputtering (RF sputtering) using an HfO₂ target and SiO₂ target with argon (Ar) gas as sputtering gas, a phase shift film 2 formed of hafnium, silicon, and oxygen was formed with a thickness of 55 nm on the transparent substrate 1.

Next, the transparent substrate 1 having the phase shift film 2 formed thereon was subjected to heat treatment for reducing film stress of the phase shift film 2. A transmittance and a phase difference of the phase shift film 2 after the heat treatment to a light of 193 nm wavelength were measured using a phase shift measurement apparatus (MPM193 manufactured by Lasertec), and a transmittance was 27.6% and a phase difference was 177.2 degrees. Further, each optical characteristic of the phase shift film 2 was measured using a spectroscopic ellipsometer (M-2000D manufactured by J. A. Woollam), and a refractive index n was 2.769 and an extinction coefficient k was 0.259 in a light of 193 nm wavelength. A phase shift film was formed on another transparent substrate under the same film forming conditions. Further, the phase shift film was analyzed by X-ray photoelectron spectroscopy (XPS analysis). As a result, the composition of the phase shift film was Hf:Si:O=25.5:8.6:65.9 (atom % ratio). Hf/[Hf+Si] ratio was 0.75.

Next, the transparent substrate 1 having the phase shift film 2 formed thereon was placed in a single-wafer RF sputtering apparatus, and reactive sputtering (RF sputtering) was carried out using a chromium (Cr) target under a mixed gas environment of argon (Ar), carbon dioxide (CO₂), and helium (He). Thus, a light shielding film (CrOC film) 3 formed of chromium, oxygen, and carbon was formed with a film thickness of 49 nm in contact with the phase shift film 2. A light shielding film was formed on another transparent substrate under the same film forming conditions. Further, the light shielding film was analyzed by X-ray photoelectron spectroscopy (XPS analysis), and the composition of the light shielding film was Cr:O:C=70.8:15.1:14.1 (atom % ratio).

Next, the transparent substrate 1 having the light shielding film (CrOC film) 3 formed thereon was subjected to heat treatment. After the heat treatment, a spectrophotometer (Cary4000 manufactured by Agilent Technologies) was used on the transparent substrate 1 having the phase shift film 2 and the light shielding film 3 stacked thereon to measure an optical density of the stacked structure of the phase shift film 2 and the light shielding film 3 to an ArF excimer laser light wavelength (about 193 nm), confirming the value of 3.0 or more.

Next, the transparent substrate 1 having the phase shift film 2 and the light shielding film 3 stacked thereon was placed in a single-wafer RF sputtering apparatus, and by RF sputtering using a silicon dioxide (SiO₂) target and argon (Ar) gas as sputtering gas, a hard mask film 4 formed of silicon and oxygen was formed with a thickness of 12 nm on the light shielding film 3. Further, a predetermined cleaning treatment was carried out to form a mask blank 100 of Example 1.

### [Manufacture of Phase Shift Mask]

Next, a half tone phase shift mask 200 of Example 1 was manufactured through the following procedure using the mask blank 100 of Example 1. First, a surface of the hard mask film 4 was subjected to HMDS treatment. Subsequently, a resist film of a chemically amplified resist for electron beam writing was formed with a thickness of 80 nm in contact with a surface of the hard mask film 4 by spin coating. Next, a first pattern, which is a phase shift pattern to be formed in the phase shift film 2, was written by an electron beam on the resist film, predetermined cleaning and developing treatments were conducted, and a resist pattern 5a having the first pattern was formed (see FIG. 2A).

Next, dry etching using CF₄ gas was conducted with the resist pattern 5a as a mask, and a first pattern (hard mask pattern 4a) was formed in the hard mask film 4 (see FIG. 2B).

Next, the resist pattern 5a was removed. Subsequently, dry etching was conducted using mixed gas of chlorine gas (Cl₂) and oxygen gas (O₂) with the hard mask pattern 4a as a mask, and a first pattern (light shielding pattern 3a) was formed in the light shielding film 3 (see FIG. 2C).

Next, dry etching was conducted using mixed gas of BCl₃ gas and Cl₂ gas with the light shielding pattern 3a as a mask, and a first pattern (phase shift pattern 2a) was formed in the phase shift film 2, and also the hard mask pattern 4a was removed (see FIG. 2D).

Next, a resist film of a chemically amplified resist for electron beam writing was formed with a film thickness of 150 nm on the light shielding pattern 3a by spin coating. Next, a second pattern, which is a pattern (pattern including light shielding band pattern) to be formed in the light shielding film, was written on the resist film by exposure, further predetermined treatments such as developing were carried out to form a resist pattern 6b having the light shielding pattern (see FIG. 2E). Subsequently, dry etching was conducted using mixed gas of chlorine gas (Cl₂) and oxygen gas (O₂) with the resist pattern 6b as a mask, and a second pattern (light shielding pattern 3b) was formed in the light shielding film 3 (see FIG. 2F). Further, the resist pattern 6b was removed, predetermined treatments such as cleaning were carried out, and the phase shift mask 200 was obtained (see FIG. 2G).

### [Evaluation of Pattern Transfer Performance]

On the phase shift mask 200 manufactured by the above procedures, a simulation of a transfer image was made using AIMS193 (manufactured by Carl Zeiss) assuming that an exposure transfer was made on a resist film on a semiconductor device at an exposure light of 193 nm wavelength. The simulated exposure transfer image was inspected, and the design specification was fully satisfied with high CD in-plane uniformity. It can be considered from this result that a circuit pattern to be finally formed on the semiconductor device can be formed at a high precision when the phase shift mask 200 of Example 1 is set on a mask stage of an exposure apparatus and a resist film on the semiconductor device is subjected to exposure transfer.

### Example 2

### [Manufacture of Mask Blank]

A mask blank 100 of Example 2 was manufactured through the same procedure as Example 1, except for the phase shift film 2 and a film thickness of the light shielding film 3. The phase shift film 2 of Example 2 has film forming conditions that are different from the phase shift film 2 of Example 1. Concretely, the transparent substrate 1 was placed in a single-wafer RF sputtering apparatus, and by changing the power ratio applied to each of an HfO₂ target and an SiO₂ target, reactive sputtering (RF sputtering) was performed under an argon (Ar) gas atmosphere. Through the above procedure, a phase shift film 2 formed of hafnium, silicon, and oxygen was formed with a thickness of 57.8 nm on the transparent substrate 1.

Next, the transparent substrate 1 having the phase shift film 2 formed thereon was subjected to heat treatment for reducing film stress of the phase shift film 2. A transmittance and a phase difference of the phase shift film 2 after the heat treatment to a light of 193 nm wavelength were measured using a phase shift measurement apparatus (MPM193 manufactured by Lasertec), and a transmittance was 32.0% and a phase difference was 176.9 degrees. Further, each optical characteristic of the phase shift film 2 was measured using a spectroscopic ellipsometer (M-2000D manufactured by J. A. Woollam), and a refractive index n was 2.681 and an extinction coefficient k was 0.216 in a light of 193 nm wavelength. A phase shift film was formed on another transparent substrate under the same film forming conditions. Further, the phase shift film was analyzed by an X-ray photoelectron spectroscopy (XPS analysis). As a result, the composition of the phase shift film was Hf:Si:O=23.4:10.5:66.1 (atom % ratio). Further, Hf/[Hf+Si] ratio was 0.69.

Next, through the same procedure as Example 1, a light shielding film (CrOC film) 3 formed of chromium, oxygen, and carbon was formed with a film thickness of 51 nm in contact with the phase shift film 2. A spectrophotometer (Cary4000 manufactured by Agilent Technologies) was used on the transparent substrate 1 having the phase shift film 2 and the light shielding film 3 of Example 2 stacked thereon to measure an optical density of the stacked structure of the phase shift film 2 and the light shielding film 3 to an ArF excimer laser light wavelength (about 193 nm), confirming the value of 3.0 or more.

### [Manufacture and Evaluation of Phase Shift Mask]

Next, using the mask blank 100 of Example 2, a phase shift mask 200 of Example 2 was manufactured through the same procedure as Example 1. On the phase shift mask 200 of Example 2, a simulation of a transfer image was made using AIMS193 (manufactured by Carl Zeiss) assuming that an exposure transfer was made on a resist film on a semiconductor device at an exposure light of wavelength 193 nm, similar to Example 1. The simulated exposure transfer image was inspected, and the design specification was fully satisfied with high CD in-plane uniformity. It can be considered from this result that a circuit pattern to be finally formed on the semiconductor device can be formed at a high precision when the phase shift mask 200 of Example 2 is set on a mask stage of an exposure apparatus and a resist film on the semiconductor device is subjected to exposure transfer.

### Example 3

### [Manufacture of Mask Blank]

A mask blank 100 of Example 3 was manufactured through the same procedure as Example 1, except for the phase shift film 2 and a film thickness of the light shielding film 3. The phase shift film 2 of Example 3 has film forming conditions that are different from the phase shift film 2 of Example 1. Concretely, the transparent substrate 1 was placed in a single-wafer RF sputtering apparatus, and by changing the power ratio applied to each of an HfO₂ target and an SiO₂ target, reactive sputtering (RF sputtering) was performed under an argon (Ar) gas atmosphere. Through the above procedure, a phase shift film 2 formed of hafnium, silicon, and oxygen was formed with a thickness of 60.7 nm on the transparent substrate 1.

Next, the transparent substrate 1 having the phase shift film 2 formed thereon was subjected to heat treatment for reducing film stress of the phase shift film 2. Transmittance and phase difference of the phase shift film 2 after the heat treatment to a light of 193 nm wavelength were measured using a phase shift measurement apparatus (MPM193 manufactured by Lasertec), and the transmittance was 36.8% and the phase difference was 177.1 degrees. Further, each optical characteristic of the phase shift film 2 was measured using a spectroscopic ellipsometer (M-2000D manufactured by J. A. Woollam), and a refractive index n was 2.603 and an extinction coefficient k was 0.178 in a light of 193 nm wavelength. A phase shift film was formed on another transparent substrate under the same film forming conditions. Further, the phase shift film was analyzed by an X-ray photoelectron spectroscopy (XPS analysis). As a result, the composition of the phase shift film was Hf:Si:O=21.8:12.3:65.9 (atom % ratio). Further, Hf/[Hf+Si] ratio was 0.64.

Next, through the same procedure as Example 1, a light shielding film (CrOC film) 3 formed of chromium, oxygen, and carbon was formed with a film thickness of 52 nm in contact with the phase shift film 2. A spectrophotometer (Cary4000 manufactured by Agilent Technologies) was used on the transparent substrate 1 having the phase shift film 2 and the light shielding film 3 of Example 3 stacked thereon to measure an optical density of the stacked structure of the phase shift film 2 and the light shielding film 3 to an ArF excimer laser light wavelength (about 193 nm), confirming the value of 3.0 or more.

### [Manufacture and Evaluation of Phase Shift Mask]

Next, using the mask blank 100 of Example 3, a phase shift mask 200 of Example 3 was manufactured through the same procedure as Example 1. On the phase shift mask 200 of Example 3, a simulation of a transfer image was made using AIMS193 (manufactured by Carl Zeiss) assuming that an exposure transfer was made on a resist film on a semiconductor device at an exposure light of wavelength 193 nm, similar to Example 1. The simulated exposure transfer image was inspected, and the design specification was fully satisfied with high CD in-plane uniformity. It can be considered from this result that a circuit pattern to be finally formed on the semiconductor device can be formed at a high precision when the phase shift mask 200 of Example 3 is set on a mask stage of an exposure apparatus and a resist film on the semiconductor device is subjected to exposure transfer.

### Example 4

### [Manufacture of Mask Blank]

A mask blank 100 of Example 4 was manufactured through the same procedure as Example 1, except for the phase shift film 2 and a film thickness of the light shielding film 3. The phase shift film 2 of Example 4 has film forming conditions that are different from the phase shift film 2 of Example 1. Concretely, the transparent substrate 1 was placed in a single-wafer RF sputtering apparatus, and by changing the power ratio applied to each of an HfO₂ target and an SiO₂ target, reactive sputtering (RF sputtering) was performed under an argon (Ar) gas atmosphere. Through the above procedure, a phase shift film 2 formed of hafnium, silicon, and oxygen was formed with a thickness of 62.0 nm on the transparent substrate 1.

Next, the transparent substrate 1 having the phase shift film 2 formed thereon was subjected to heat treatment for reducing film stress of the phase shift film 2. A transmittance and a phase difference of the phase shift film 2 after the heat treatment to a light of 193 nm wavelength were measured using a phase shift measurement apparatus (MPM193 manufactured by Lasertec), and a transmittance was 38.6% and a phase difference was 177.0 degrees. Further, each optical characteristic of the phase shift film 2 was measured using a spectroscopic ellipsometer (M-2000D manufactured by J. A. Woollam), and a refractive index n was 2.569 and an extinction coefficient k was 0.167 in a light of 193 nm wavelength. A phase shift film was formed on another transparent substrate under the same film forming conditions. Further, the phase shift film was analyzed by an X-ray photoelectron spectroscopy (XPS analysis). As a result, the composition of the phase shift film was Hf:Si:O=20.1:13.9:66.0 (atom % ratio). Further, Hf/[Hf+Si] ratio was 0.59.

Next, through the same procedure as Example 1, a light shielding film (CrOC film) 3 formed of chromium, oxygen, and carbon was formed with a film thickness of 52 nm in contact with the phase shift film 2. A spectrophotometer (Cary4000 manufactured by Agilent Technologies) was used on the transparent substrate 1 having the phase shift film 2 and the light shielding film 3 of Example 4 stacked thereon to measure an optical density of the stacked structure of the phase shift film 2 and the light shielding film 3 to an ArF excimer laser light wavelength (about 193 nm), confirming the value of 3.0 or more.

### [Manufacture and Evaluation of Phase Shift Mask]

Next, using the mask blank 100 of Example 4, a phase shift mask 200 of Example 4 was manufactured through the same procedure as Example 1. On the phase shift mask 200 of Example 4, a simulation of a transfer image was made using AIMS193 (manufactured by Carl Zeiss) assuming that an exposure transfer was made on a resist film on a semiconductor device at an exposure light of wavelength 193 nm, similar to Example 1. The simulated exposure transfer image was inspected, and the design specification was fully satisfied with high CD in-plane uniformity. It can be considered from this result that a circuit pattern to be finally formed on the semiconductor device can be formed at a high precision when the phase shift mask 200 of Example 4 is set on a mask stage of an exposure apparatus and a resist film on the semiconductor device is subjected to exposure transfer.

### Comparative Example 1

### [Manufacture of Mask Blank]

A mask blank of Example 1 was manufactured through the same procedure as Example 1, except for the phase shift film and a film thickness of the light shielding film. The phase shift film of Comparative Example 1 has film forming conditions that are different from the phase shift film 2 of Example 1. Concretely, a transparent substrate was placed in a single-wafer RF sputtering apparatus, and using an HfO₂ target, reactive sputtering (RF sputtering) was performed under an argon (Ar) gas atmosphere. Through the above procedure, a phase shift film formed of hafnium and oxygen was formed with a thickness of 49.5 nm on the transparent substrate.

A transmittance and a phase difference of the phase shift film to a light of 193 nm wavelength were measured using a phase shift measurement apparatus (MPM193 manufactured by Lasertec), and a transmittance was 17.8% and a phase difference was 176.8 degrees. Further, each optical characteristic of the phase shift film was measured using a spectroscopic ellipsometer (M-2000D manufactured by J. A. Woollam), and a refractive index n was 2.964 and an extinction coefficient k was 0.408 in a light of 193 nm wavelength. Further, a ratio [Hf/[Hf+Si] of a hafnium content to a total content of hafnium and silicon by atom % in the phase shift film is 1.000.

Next, through the same procedure as Example 1, a light shielding film (CrOC film) formed of chromium, oxygen, and carbon was formed with a film thickness of 45 nm in contact with the phase shift film. A spectrophotometer (Cary4000 manufactured by Agilent Technologies) was used on the transparent substrate having the phase shift film and the light shielding film of Comparative Example 1 stacked thereon to measure an optical density of the stacked structure of the phase shift film and the light shielding film to an ArF excimer laser light wavelength (about 193 nm), confirming the value of 3.0 or more.

### [Manufacture and Evaluation of Phase Shift Mask]

Next, using the mask blank of Comparative Example 1, a phase shift mask of Comparative Example 1 was manufactured through the same procedure as Example 1. On the phase shift mask of Comparative Example 1, a simulation of a transfer image was made using AIMS193 (manufactured by Carl Zeiss) assuming that an exposure transfer was made on a resist film on a semiconductor device at an exposure light of wavelength 193 nm, similar to Example 1. The simulated exposure transfer image was inspected, and the design specification was not satisfied. This result is inferred as caused by unclear pattern transferring because of failure to sufficiently increase a transmittance of the phase shift film. It can be considered from this result that a circuit pattern to be finally formed on the semiconductor device can hardly be formed at a high precision when the phase shift mask of Comparative Example 1 is set on a mask stage of an exposure apparatus and a resist film on the semiconductor device is subjected to exposure transfer.

### Comparative Example 2

### [Manufacture of Mask Blank]

A mask blank of Comparative Example 2 was manufactured through the same procedure as Example 1, except for the phase shift film and a film thickness of the light shielding film. Concretely, a transparent substrate was placed in a single-wafer RF sputtering apparatus, and by changing the power ratio applied to each of an HfO₂ target and an SiO₂ target, reactive sputtering (RF sputtering) was performed under an argon (Ar) gas atmosphere. Through the above procedure, a phase shift film formed of hafnium, silicon, and oxygen was formed with a thickness of 93.2 nm on the transparent substrate.

Next, the transparent substrate having the phase shift film formed thereon was subjected to heat treatment for reducing film stress of the phase shift film. A transmittance and a phase difference of the phase shift film after the heat treatment to a light of 193 nm wavelength were measured using a phase shift measurement apparatus (MPM193 manufactured by Lasertec), and a transmittance was 77.4% and a phase difference was 177.0 degrees. Further, each optical characteristic of the phase shift film was measured using a spectroscopic ellipsometer (M-2000D manufactured by J. A. Woollam), and a refractive index n was 2.024 and an extinction coefficient k was 0.039 in a light of 193 nm wavelength. A phase shift film was formed on another transparent substrate under the same film forming conditions. Further, the phase shift film was analyzed by an X-ray photoelectron spectroscopy (XPS analysis). As a result, the composition of the phase shift film was Hf:Si:O=12.2:21.7:66.1 (atom % ratio). Further, Hf/[Hf+Si] ratio was 0.36.

Next, through the same procedure as Example 1, a light shielding film (CrOC film) formed of chromium, oxygen, and carbon was formed with a film thickness of 58 nm in contact with the phase shift film. A spectrophotometer (Cary4000 manufactured by Agilent Technologies) was used on the transparent substrate having the phase shift film and the light shielding film of Comparative Example 2 stacked thereon to measure an optical density of the stacked structure of the phase shift film and the light shielding film to an ArF excimer laser light wavelength (about 193 nm), confirming the value of 3.0 or more.

### [Manufacture and Evaluation of Phase Shift Mask]

Next, using the mask blank of Comparative Example 2, a phase shift mask of Comparative Example 2 was manufactured through the same procedure as Example 1. On the phase shift mask of Comparative Example 2, a simulation of a transfer image was made using AIMS193 (manufactured by Carl Zeiss) assuming that an exposure transfer was made on a resist film on a semiconductor device at an exposure light of wavelength 193 nm, similar to Example 1. The simulated exposure transfer image was inspected, and the design specification was not satisfied. This result is inferred to be caused by an excessive film thickness of the phase shift film causing reduction of the optical performance of the phase shift film so that an exposure margin could not be secured. It can be considered from this result that a circuit pattern to be finally formed on the semiconductor device can hardly be formed at a high precision when the phase shift mask of Comparative Example 2 is set on a mask stage of an exposure apparatus and a resist film on the semiconductor device is subjected to exposure transfer.

### Comparative Example 3

### [Manufacture of Mask Blank]

A mask blank of Comparative Example 3 was manufactured through the same procedure as Example 1, except for the phase shift film and a film thickness of the light shielding film. Concretely, a transparent substrate was placed in a single-wafer RF sputtering apparatus, and using an Si target, reactive sputtering (RF sputtering) was performed under a mixed gas atmosphere of argon (Ar) gas and nitrogen (N₂) gas. Through the above procedure, a phase shift film formed of silicon and nitrogen was formed with a thickness of 60.5 nm on the transparent substrate.

Next, the transparent substrate having the phase shift film formed thereon was subjected to heat treatment for reducing film stress of the phase shift film. A transmittance and a phase difference of the phase shift film after the heat treatment to a light of 193 nm wavelength were measured using a phase shift measurement apparatus (MPM193 manufactured by Lasertec), and a transmittance was 18.8% and a phase difference was 177.0 degrees. Further, each optical characteristic of the phase shift film was measured using a spectroscopic ellipsometer (M-2000D manufactured by J. A. Woollam), and a refractive index n was 2.610 and an extinction coefficient k was 0.360 in a light of 193 nm wavelength. Further, a ratio Hf/[Hf+Si] of a hafnium content to a total content of hafnium and silicon by atom % in the phase shift film is 0.000.

Next, through the same procedure as Example 1, a light shielding film (CrOC film) formed of chromium, oxygen, and carbon was formed with a film thickness of 46 nm in contact with the phase shift film. A spectrophotometer (Cary4000 manufactured by Agilent Technologies) was used on the transparent substrate having the phase shift film and the light shielding film of Comparative Example 3 stacked thereon to measure an optical density of the stacked structure of the phase shift film and the light shielding film to an ArF excimer laser light wavelength (about 193 nm), confirming the value of 3.0 or more.

### [Manufacture and Evaluation of Phase Shift Mask]

Next, using the mask blank of Comparative Example 3, a phase shift mask of Comparative Example 3 was manufactured through the same procedure as Example 1. In forming a phase shift pattern, dry etching was carried out using fluorine-based gas (CF₄ gas). On the phase shift mask of Comparative Example 3, a simulation of a transfer image was made using AIMS193 (manufactured by Carl Zeiss) assuming that an exposure transfer was made on a resist film on a semiconductor device at an exposure light of wavelength 193 nm, similar to Example 1. The simulated exposure transfer image was inspected, and the design specification was not satisfied. This result is inferred as caused by unclear pattern transferring because of failure to sufficiently increase a transmittance of the phase shift film. It can be considered from this result that a circuit pattern to be finally formed on the semiconductor device can hardly be formed at a high precision when the phase shift mask of Comparative Example 3 is set on a mask stage of an exposure apparatus and a resist film on the semiconductor device is subjected to exposure transfer.

### Comparative Example 4

### [Manufacture of Mask Blank]

A mask blank of Comparative Example 4 was manufactured through the same procedure as Example 1, except for the phase shift film and a film thickness of the light shielding film. Concretely, a transparent substrate was placed in a single-wafer RF sputtering apparatus, and using an Si target, reactive sputtering (RF sputtering) was performed under a mixed gas atmosphere of argon (Ar) gas, nitrogen (N₂) gas, and oxygen (O₂) gas. Through the above procedure, a phase shift film formed of silicon, oxygen, and nitrogen was formed with a thickness of 68.4 nm on the transparent substrate.

Next, the transparent substrate having the phase shift film formed thereon was subjected to heat treatment for reducing film stress of the phase shift film. A transmittance and a phase difference of the phase shift film after the heat treatment to a light of 193 nm wavelength were measured using a phase shift measurement apparatus (MPM193 manufactured by Lasertec), and a transmittance was 27.6% and a phase difference was 177.0 degrees. Further, each optical characteristic of the phase shift film was measured using a spectroscopic ellipsometer (M-2000D manufactured by J. A. Woollam), and a refractive index n was 2.419 and an extinction coefficient k was 0.249 in a light of 193 nm wavelength. Further, a ratio Hf/[Hf+Si] of a hafnium content to a total content of hafnium and silicon by atom % in the phase shift film is 0.000.

Next, through the same procedure as Example 1, a light shielding film (CrOC film) 3 formed of chromium, oxygen, and carbon was formed with a film thickness of 49 nm in contact with the phase shift film 2. A spectrophotometer (Cary4000 manufactured by Agilent Technologies) was used on the transparent substrate having the phase shift film and the light shielding film of Comparative Example 4 stacked thereon to measure an optical density of the stacked structure of the phase shift film and the light shielding film to an ArF excimer laser light wavelength (about 193 nm), confirming the value of 3.0 or more.

### [Manufacture and Evaluation of Phase Shift Mask]

Next, using the mask blank of Comparative Example 4, a phase shift mask of Comparative Example 4 was manufactured through the same procedure as Example 1. In forming a phase shift pattern, dry etching was carried out using fluorine-based gas. On the phase shift mask of Comparative Example 4, a simulation of a transfer image was made using AIMS193 (manufactured by Carl Zeiss) assuming that an exposure transfer was made on a resist film on a semiconductor device at an exposure light of wavelength 193 nm, similar to Example 1. The simulated exposure transfer image was inspected, and the design specification was not satisfied. This result is inferred to be caused by an excessive film thickness of the phase shift film causing reduction of the optical performance of the phase shift film so that an exposure margin could not be secured. It can be considered from this result that a circuit pattern to be finally formed on the semiconductor device can hardly be formed at a high precision when the phase shift mask of Comparative Example 4 is set on a mask stage of an exposure apparatus and a resist film on the semiconductor device is subjected to exposure transfer.

### DESCRIPTION OF REFERENCE NUMERALS

1 transparent substrate
2 phase shift film
2a phase shift pattern
3 light shielding film
3a, 3b light shielding pattern
4 hard mask film
4a hard mask pattern
5a resist pattern
6b resist pattern
100 mask blank
200 phase shift mask

1. A mask blank comprising a phase shift film on a transparent substrate,
wherein the phase shift film contains hafnium, silicon, and oxygen,
wherein a ratio of a hafnium content to a total content of hafnium and silicon in the phase shift film by atom % is 0.4 or more,
wherein a refractive index n of the phase shift film to a wavelength of an exposure light of an Arf excimer laser is 2.5 or more, and
wherein an extinction coefficient k of the phase shift film to a wavelength of the exposure light is 0.30 or less.

2. The mask blank according to claim 1, wherein a refractive index n of the phase shift film to a wavelength of the exposure light is 2.9 or less.

3. The mask blank according to claim 1, wherein an extinction coefficient k of the phase shift film to a wavelength of the exposure light is 0.05 or more.

4. The mask blank according to claim 1, wherein the phase shift film has an oxygen content of 60 atom % or more.

5. The mask blank according to claim 1, wherein the phase shift film has a film thickness of 65 nm or less.

6. The mask blank according to claim 1, wherein the phase shift film contains hafnium, silicon, and oxygen at a total content of 90 atom % or more.

7. The mask blank according to claim 1, wherein the phase shift film has a function to transmit the exposure light at a transmittance of 20% or more, and a function to generate a phase difference of 150 degrees or more and 210 degrees or less between the exposure light transmitted through the phase shift film and the exposure light transmitted through the air for a same distance as a thickness of the phase shift film.

8. The mask blank according to claim 1 comprising a light shielding film on the phase shift film.

9. A phase shift mask comprising a phase shift film having a transfer pattern on a transparent substrate,
wherein the phase shift film contains hafnium, silicon, and oxygen,
wherein a ratio of a hafnium content to a total content of hafnium and silicon in the phase shift film by atom % is 0.4 or more,
wherein a refractive index n of the phase shift film to a wavelength of an exposure light of an Arf excimer laser is 2.5 or more, and
wherein an extinction coefficient k of the phase shift film to a wavelength of the exposure light is 0.30 or less.

10. The phase shift mask according to claim 9, wherein a refractive index n of the phase shift film to a wavelength of the exposure light is 2.9 or less.

11. The phase shift mask according to claim 9, wherein an extinction coefficient k of the phase shift film to a wavelength of the exposure light is 0.05 or more.

12. The phase shift mask according to claim 9, wherein the phase shift film has an oxygen content of 60 atom % or more.

13. The phase shift mask according to claim 9, wherein the phase shift film has a film thickness of 65 nm or less.

14. The phase shift mask according to claim 9, wherein the phase shift film contains hafnium, silicon, and oxygen at a total content of 90 atom % or more.

15. The phase shift mask according to claim 9, wherein the phase shift film has a function to transmit the exposure light at a transmittance of 20% or more, and a function to generate a phase difference of 150 degrees or more and 210 degrees or less between the exposure light transmitted through the phase shift film and the exposure light transmitted through the air for a same distance as a thickness of the phase shift film.

16. The phase shift mask according to claim 9 comprising a light shielding film having a pattern comprising a light shielding band on the phase shift film.

17. A method of manufacturing a semiconductor device comprising the step of transferring a transfer pattern to a resist film on a semiconductor substrate by exposure using the phase shift mask according to claim 16.

18. The mask blank according to claim 2, wherein an extinction coefficient k of the phase shift film to a wavelength of the exposure light is 0.05 or more.

19. The mask blank according to 18, wherein the phase shift film has an oxygen content of 60 atom % or more.

20. The mask blank according to claim 19, wherein the phase shift film has a film thickness of 65 nm or less.
